(19) United States
(12) Patent Application Publication
(10) Pub. No.: US 2012/0327327 A1
(43) Pub. Date: Dec. 27, 2012

(54) MOBILE TERMINAL

(76) Inventors: Wonseok Joo, Seoul (KR); Hyunseok Oh, Seoul (KR); Kanghee Min, Seoul (KR)

(21) Appl. No.: 13/352,922

(22) Filed: Jan. 18, 2012

(30) Foreign Application Priority Data
Jun. 27, 2011 (KR) 10-2011-0062542

(51) Int. Cl. G02F 1/13357; H05K 1/00; H05K 7/00

(52) U.S. Cl. 349/58; 361/679.01; 361/749

(57) ABSTRACT

A mobile terminal includes a frame having a hollow portion, a liquid crystal panel received in the hollow portion, the liquid crystal panel forming an image thereon, a backlight unit disposed at the rear of the liquid crystal panel to emit light toward the liquid crystal panel, a reflection sheet disposed at the rear of the backlight unit and fixed to the frame to obscure the hollow portion, the reflection sheet reflecting light leaked to a lower side of the backlight unit, a supporting member forming a space to receive the frame therein, the supporting member supporting the frame, and a contact restricting unit to space the reflection sheet apart from the supporting member.

### CROSS-REFERENCE TO RELATED APPLICATION

Pursuant to 35 U.S.C. §119, this application claims the benefit of earlier filing date and right of priority to Korean Application No. 10-2011-0062542, filed in Republic of Korea on Jun. 27, 2011, the contents of which are incorporated by reference herein in their entirety.

### BACKGROUND OF THE INVENTION

1. Field of the Invention

This specification relates to a mobile terminal with a display module.

2. Background of the Invention

Mobile terminals are electronic devices which are portable and have at least one of voice and telephone call functions, information input and/or output functions, a data storage function and the like.

As it becomes multifunctional, the mobile terminal can be allowed to capture still images or moving images, play music or video files, play games, receive broadcast and the like, so as to be implemented as an integrated multimedia player.

Various attempts have been made for the multimedia device in aspect of hardware or software in order to implement such complicated functions. As an example, a user interface environment is provided for the user to easily or conveniently retrieve or select a function.

In addition to those attempts, an approach to improve the hardware function has been made. This approach includes not only structural changes but also improvements for providing a mobile terminal with improved reliability, and protecting a liquid crystal panel of a display module.

### SUMMARY OF THE INVENTION

Therefore, an object of the invention is to provide a mobile terminal with a display module capable of protecting a liquid crystal panel even when being affected by an external impact or exposed to high temperature.

Another aspect of the invention is to provide a mobile terminal with a display module allowing a mobile terminal which is slimmer and has improved reliability.

To achieve these and other objects and in accordance with the purpose of the invention, as embodied and broadly described herein, there is provided a mobile terminal including a frame having a hollow portion, a liquid crystal panel received in the hollow portion, the liquid crystal panel forming an image thereon, a backlight unit disposed at the rear of the liquid crystal panel to emit light toward the liquid crystal panel, a reflection sheet disposed at the rear of the backlight unit and fixed to the frame to obscure the hollow portion, the reflection sheet reflecting light leaked to a lower side of the backlight unit, a supporting member forming a space to place the frame thereon, the supporting member supporting the frame, and a contact restricting unit to space the reflection sheet apart from the supporting member.

In accordance with one aspect, the contact restricting unit may be interposed between the frame and the supporting member, and include a connection frame protruding from the reflection sheet. The connection frame may extend from the frame.

In accordance with another aspect, the contact restricting unit may include a recess portion recessed into a bottom surface of the supporting member that faces the reflection sheet. The frame may be fixed onto the bottom surface of the supporting member, and the reflection sheet may be disposed with being spaced apart from a bottom surface of the recess portion by a preset interval.

In accordance with another aspect, the mobile terminal may further include a flexible printed circuit board electrically connected to the liquid crystal panel, and the contact restricting unit may include a through hole formed through one surface of the supporting member such that the flexible printed circuit board can be inserted therethrough. The flexible printed circuit board may be disposed to be inserted through the through hole in a non-overlapped state with the reflection sheet and the supporting member.

In accordance with another aspect, the contact restricting unit may include a damping sheet disposed between the reflection sheet and the supporting member to adsorb impact transferred to the reflection sheet. The damping sheet may be attached onto a rear surface of the reflection sheet.

In accordance with another aspect, the frame may have a recess to receive an end portion of the reflection sheet, and the reflection sheet may be inserted into the recess to be fixed to the frame so as to support the liquid crystal panel and the backlight unit.

In accordance with another embodiment, there is provided a mobile terminal including a display module having a frame with a hollow portion, and a reflection sheet fixed onto the frame to obscure the hollow portion so as to form a bottom surface, the reflection sheet reflecting light leaked to a lower side of a backlight unit, the display module displaying visual information, a housing having a receiving portion forming a space for reception of the display module therein, the housing supporting the frame, and a contact restricting unit to space the display module apart from a bottom surface forming the receiving portion of the housing.

In accordance with one aspect, the contact restricting unit may include a connection frame extending from the frame and protruding from the reflection sheet.

In accordance with another aspect, the contact restricting unit may include a recess portion recessed into a bottom surface of the housing that faces the reflection sheet.

In accordance with another aspect, the contact restricting unit may include a damping sheet disposed between the reflection sheet and the housing to adsorb impact transferred to the reflection sheet, and a through hole formed through one surface of the housing to allow a flexible printed circuit board to be inserted therethrough, the flexible printed circuit board electrically connected to the display module. The flexible printed circuit board may obscure a rear surface of the housing.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this specification, illustrate exemplary embodiments and together with the description serve to explain the principles of the invention.

In the drawings:

FIG. 1 is a block diagram of a mobile terminal in accordance with one embodiment of the invention;

FIG. 2 is a front perspective view of the mobile terminal;

FIG. 3 is a rear perspective view of the mobile terminal shown in FIG. 2;

FIG. 4 is an exploded perspective view of the mobile terminal shown in FIG. 2;

FIG. 5 is a sectional view of the mobile terminal of FIG. 2;

FIG. 6 is a sectional view showing another embodiment of a mobile terminal in accordance with the invention;

FIG. 7 is an exploded perspective view of the another embodiment of the mobile terminal;

FIG. 8 is a sectional view of the mobile terminal shown in FIG. 7;

FIG. 9 is an exploded perspective view showing another embodiment of a mobile terminal in accordance with the invention; and

FIG. 10 is a sectional view of the mobile terminal shown in FIG. 9.

### DETAILED DESCRIPTION OF THE INVENTION

Description will now be given in detail of a mobile terminal according to the various embodiments, with reference to the accompanying drawings.

For the sake of brief description with reference to the drawings, the same or equivalent components will be provided with the same reference numbers, and description thereof will not be repeated. Hereinafter, suffixes “module” and “unit or portion” for components used herein in description are merely provided only for facilitation of preparing this specification, and thus they are not granted a specific meaning or function.

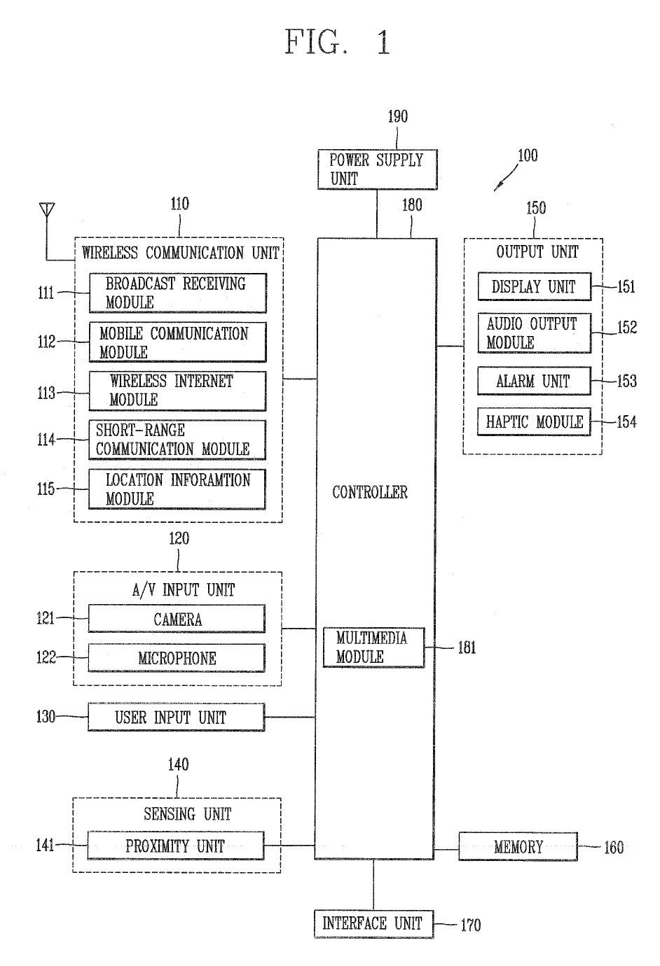

Mobile terminals described in this specification may include cellular phones, smart phones, laptop computers, digital broadcasting terminals, personal digital assistants (PDAs), portable multimedia players (PMPs), navigators, and Tablet PCs. FIG. 1 is a block diagram of a mobile terminal 100 in accordance with one embodiment.

The mobile terminal 100 may comprise components, such as a wireless communication unit 110, an Audio/Video (A/V) input unit 120, a user input unit 130, a sensing unit 140, an output unit 150, a memory 160, an interface unit 170, a controller 180, a power supply 190 and the like. FIG. 1 shows the mobile terminal 100 having various components, but it is understood that implementing all of the illustrated components is not a requirement. Greater or fewer components may alternatively be implemented.

Hereinafter, each component is described in sequence.

The wireless communication unit 110 may typically include one or more modules which permit wireless communications between the mobile terminal 100 and a wireless communication system or between the mobile terminal 100 and a network within which the mobile terminal 100 is located. For example, the wireless communication unit 110 may include a broadcast receiving module 111, a mobile communication module 112, a wireless Internet module 113, a short-range communication module 114, a location information module 115 and the like.

The broadcast receiving module 111 receives a broadcast signal and/or broadcast associated information from an external broadcast managing entity via a broadcast channel.

The broadcast channel may include a satellite channel and a terrestrial channel. The broadcast managing entity may indicate a server which generates and transmits a broadcast signal and/or broadcast associated information or a server which receives a pre-generated broadcast signal and/or broadcast associated information and sends them to the mobile terminal. The broadcast signal may be implemented as a TV broadcast signal, a radio broadcast signal, and a data broadcast signal, among others. The broadcast signal may further include a data broadcast signal combined with a TV or radio broadcast signal.

Examples of broadcast associated information may include information associated with a broadcast channel, a broadcast program, a broadcast service provider, and the like. The broadcast associated information may be provided via a mobile communication network, and received by the mobile communication module 112.

The broadcast associated information may be implemented in various formats. For instance, broadcast associated information may include Electronic Program Guide (EPG) of Digital Multimedia Broadcasting (DMB), Electronic Service Guide (ESG) of Digital Video Broadcast-Handheld (DVB-H), and the like.

The broadcast receiving module 111 may be configured to receive digital broadcast signals transmitted from various types of broadcast systems. Such broadcast systems may include Digital Multimedia Broadcasting-Terrestrial (DMB-T), Digital Multimedia Broadcasting-Satellite (DMB-S), Media Forward Link Only (MediaFLO), Digital Video Broadcast-Handheld (DVB-H), Integrated Services Digital Broadcast-Terrestrial (ISDB-T) and the like. The broadcast receiving module 111 may be configured to be suitable for every broadcast system transmitting broadcast signals as well as the digital broadcasting systems.

Broadcast signals and/or broadcast associated information received via the broadcast receiving module 111 may be stored in a suitable device, such as a memory 160.

The mobile communication module 112 transmits and receives wireless signals to and from at least one network entity (e.g., base station, an external mobile terminal, a server, etc.) on a mobile communication network. Here, the wireless signals may include audio call signal, video (telephony) call signal, or various formats of data according to transmission and reception of text and multimedia messages.

The wireless Internet module 113 supports wireless Internet access for the mobile terminal. This module may be internally or externally coupled to the mobile terminal 100. Examples of such wireless Internet access may include Wireless LAN (WLAN) (Wi-Fi), Wireless Broadband (Wibro), Worldwide Interoperability for Microwave Access (Wimax), High Speed Downlink Packet Access (HSDPA) and the like.

The short-range communication module 114 denotes a module for short-range communications. Suitable technologies for implementing this module may include BLUETOOTH™, Radio Frequency IDentification (RFID), Infrared Data Association (IrDA), Ultra-WideBand (UWB), ZigBee™, and the like.

The location information module 115 denotes a module for detecting or calculating a position of a mobile terminal. An example of the location information module 115 may include a Global Position System (GPS) module.

Referring to FIG. 1, the A/V input unit 120 is configured to provide audio or video signal input to the mobile terminal. The A/V input unit 120 may include a camera 121 and a microphone 122. The camera 121 receives and processes image frames of still pictures or video obtained by image sensors in a video call mode or a capturing mode. The processed image frames may be displayed on a display unit 151.

The image frames processed by the camera 121 may be stored in the memory 160 or transmitted via the wireless communication unit 110. Two or more cameras 121 may be provided according to the configuration of the mobile terminal.

The microphone 122 may receive an external audio signal while the mobile terminal is in a particular mode, such as a phone call mode, a recording mode, a voice recognition mode, or the like. This audio signal is processed into digital data. The processed digital data is converted for output into a format transmittable to a mobile communication base station via the mobile communication module 112 in case of the phone call mode. The microphone 122 may include assorted noise removing algorithms to remove noise generated in the course of receiving the external audio signal.

The user input unit 130 may generate input data input by a user to control the operation of the mobile terminal. The user input unit 130 may include a keypad, a dome switch, a touchpad (e.g., static pressure/capacitance), a jog wheel, a jog switch and the like.

The sensing unit 140 provides status measurements of various aspects of the mobile terminal. For instance, the sensing unit 140 may detect an open/close status of the mobile terminal, a change in a location of the mobile terminal 100, a presence or absence of user contact with the mobile terminal 100, the location of the mobile terminal 100, acceleration/deceleration of the mobile terminal 100, and the like, so as to generate a sensing signal for controlling the operation of the mobile terminal 100. For example, regarding a slide-type mobile terminal, the sensing unit 140 may sense whether a sliding portion of the mobile terminal is open or closed. Other examples include sensing functions, such as the sensing unit 140 sensing the presence or absence of power provided by the power supply 190, the presence or absence of a coupling or other connection between the interface unit 170 and an external device. In addition, the sensing unit 140 may include a proximity sensor 141.

The output unit 150 is configured to output an audio signal, a video signal or a tactile signal. The output unit 150 may include a display unit 151, an audio output module 152, an alarm unit 153 and a haptic module 154.

The display unit 151 may output information processed in the mobile terminal 100. For example, when the mobile terminal is operating in a phone call mode, the display unit 151 will provide a User Interface (UI) or a Graphic User Interface (GUI), which includes information associated with the call. As another example, if the mobile terminal is in a video call mode or a capturing mode, the display unit 151 may additionally or alternatively display images captured and/or received.

The display unit 151 may be implemented using, for example, at least one of a Liquid Crystal Display (LCD), a Thin Film Transistor-Liquid Crystal Display (TFT-LCD), an Organic Light-Emitting Diode (OLED), a flexible display, a three-dimensional (3D) display, or the like.

Some of such displays 151 may be implemented as a transparent type or an optical transparent type through which the exterior is visible, which is referred to as ‘transparent display’. A representative example of the transparent display may include a Transparent OLED (TOLED), and the like. The rear surface of the display unit 151 may also be implemented to be optically transparent. Under this configuration, a user can view an object positioned at a rear side of a terminal body through a region occupied by the display unit 151 of the terminal body.

The display unit 151 may be implemented as a plurality of displays according to a configured aspect of the mobile terminal 100. For instance, the plurality of displays 151 may be arranged on one surface to be spaced apart from or integrated with each other, or may be arranged on different surfaces.

Here, if the display unit 151 and a touch sensitive sensor (referred to as a touch sensor) have a layered structure therebetween, the structure may be referred to as a touch screen. The display unit 151 may be used as an input device as well as an output device. The touch sensor may be implemented as a touch film, a touch sheet, a touch pad, and the like.

The touch sensor may be configured to convert changes of pressure applied to a specific part of the display unit 151, or a capacitance occurring from a specific part of the display unit 151, into electric input signals. In addition, the touch sensor may be configured to sense not only a touched position and a touched area, but also a touch pressure.

When touch inputs are sensed by the touch sensors, corresponding signals are transmitted to a touch controller. The touch controller processes the received signals, and then transmits corresponding data to the controller 180. Accordingly, the controller 180 may sense which region of the display unit 151 has been touched.

Still referring to FIG. 1, a proximity sensor 141 may be arranged at an inner region of the mobile terminal 100 covered by the touch screen, or near the touch screen. The proximity sensor 141 indicates a sensor to sense the presence or absence of an object approaching a surface to be sensed, or an object disposed near a surface to be sensed, by using an electromagnetic field or infrared rays without a mechanical contact. The proximity sensor 141 has a longer lifespan and a more enhanced utility than a contact sensor.

The proximity sensor 141 may include a transmissive type photoelectric sensor, a direct reflective type photoelectric sensor, a minor reflective type photoelectric sensor, a high-frequency oscillation proximity sensor, a capacitance type proximity sensor, a magnetic type proximity sensor, an infrared rays proximity sensor, and so on. When the touch screen is implemented as a capacitance type, proximity of a pointer to the touch screen is sensed by changes of an electromagnetic field. In this case, the touch screen (touch sensor) may be categorized into a proximity sensor.

Hereinafter, for the sake of brief explanation, a status that the pointer is positioned to be proximate onto the touch screen without contact will be referred to as ‘proximity touch’, whereas a status that the pointer substantially comes in contact with the touch screen will be referred to as ‘contact touch’. For the position corresponding to the proximity touch of the pointer on the touch screen, such position corresponds to a position where the pointer faces perpendicular to the touch screen upon the proximity touch of the pointer.

The proximity sensor 141 senses proximity touch and proximity touch patterns (e.g., distance, direction, speed, time, position, moving status, etc.). Information relating to the sensed proximity touch and the sensed proximity touch patterns may be output onto the touch screen.

The audio output module 152 may output audio data received from the wireless communication unit 110 or stored in the memory 160, in a call-receiving mode, a call-placing mode, a recording mode, a voice recognition mode, a broadcast reception mode, and so on. The audio output module 152 may output audio signals relating to functions performed in the mobile terminal 100, e.g., sound alarming a call received or a message received, and so on. The audio output module 152 may include a receiver, a speaker, a buzzer, and so on.

The alarm unit 153 outputs signals notifying occurrence of events from the mobile terminal 100. The events occurring from the mobile terminal 100 may include call received, message received, key signal input, touch input, and so on. The alarm unit 153 may output not only video or audio signals, but also other types of signals such as signals notifying occurrence of events in a vibration manner. Since the video or audio signals can be output through the display unit 151 or the audio output module 152, the display unit 151 and the audio output module 152 may be categorized as part of the alarm unit 153.

The haptic module 154 generates various tactile effects which a user can feel. A representative example of the tactile effects generated by the haptic module 154 includes vibration. Vibration generated by the haptic module 154 may have a controllable intensity, a controllable pattern, and so on. For instance, different vibration may be output in a synthesized manner or in a sequential manner.

The haptic module 154 may generate various tactile effects, including not only vibration, but also arrangement of pins vertically moving with respect to a skin being touched (contacted), air injection force or air suction force through an injection hole or a suction hole, touch by a skin surface, presence or absence of contact with an electrode, effects by stimulus such as an electrostatic force, reproduction of cold or hot feeling using a heat absorbing device or a heat emitting device, and the like.

The haptic module 154 may be configured to transmit tactile effects (signals) through a user's direct contact, or a user's muscular sense using a finger or a hand. The haptic module 154 may be implemented as a plurality according to the configuration of the mobile terminal 100.

The memory 160 may store a program for the processing and control of the controller 180. Alternatively, the memory 160 may temporarily store input/output data (e.g., phonebook data, messages, still images, video and the like). In addition, the memory 160 may store data related to various patterns of vibrations and audio output upon the touch input on the touch screen.

The memory 160 may be implemented using any type of suitable storage medium including a flash memory type, a hard disk type, a memory card type (e.g., SD or DX memory), Random Access Memory (RAM), Static Random Access Memory (SRAM), Read-Only Memory (ROM), Electrically Erasable Programmable Read-Only Memory (EEPROM), Programmable Read-Only Memory (PROM), magnetic memory, magnetic disk, optical disk, and the like. In addition, the mobile terminal 100 may operate a web storage which performs the storage function of the memory 160 on the Internet.

The interface unit 170 may generally be implemented to interface the mobile terminal with external devices. The interface unit 170 may allow a data reception from an external device, a power delivery to each component in the mobile terminal 100, or a data transmission from the mobile terminal 100 to an external device. The interface unit 170 may include, for example, wired/wireless headset ports, external charger ports, wired/wireless data ports, memory card ports, ports for coupling devices having an identification module, audio Input/Output (I/O) ports, video I/O ports, earphone ports, and the like.

The identification module may be configured as a chip for storing various information required to authenticate an authority to use the mobile terminal 100, which may include a User Identity Module (UIM), a Subscriber Identity Module (SIM), and the like. In addition, the device having the identification module (hereinafter, referred to as ‘identification device’) may be implemented in a smart card. Hence, the identification device can be coupled to the mobile terminal 100 via a port.

In addition, the interface unit 170 may serve as a path for power to be supplied from an external cradle to the mobile terminal 100 when the mobile terminal 100 is connected to the external cradle or as a path for transferring various command signals input from the cradle by a user to the mobile terminal 100. Such various command signals or power input from the cradle may operate as signals for recognizing that the mobile terminal 100 has accurately been mounted to the cradle.

The controller 180 typically controls the overall operations of the mobile terminal 100. For example, the controller 180 performs the control and processing associated with telephony calls, data communications, video calls, and the like. The controller 180 may include a multimedia module 181 which provides multimedia playback. The multimedia module 181 may be configured as part of the controller 180 or as a separate component. The controller 180 can perform a pattern recognition processing so as to recognize writing or drawing input on the touch screen as text or image.

The power supply 190 provides power required by various components under the control of the controller 180. The provided power may be internal power, external power, or combination thereof.

Various embodiments described herein may be implemented in a computer-readable medium using, for example, software, hardware, or some combination thereof.

For a hardware implementation, the embodiments described herein may be implemented within one or more Application Specific Integrated Circuits (ASICs), Digital Signal Processors (DSPs), Digital Signal Processing Devices (DSPDs), Programmable Logic Devices (PLDs), Field Programmable Gate Arrays (FPGAs), processors, microprocessors, other electronic units designed to perform the functions described herein, or a selective combination thereof. In some cases, such embodiments are implemented by the controller 180.

For software implementation, the embodiments such as procedures and functions may be implemented together with separate software modules each of which performs at least one of functions and operations. The software codes can be implemented with a software application written in any suitable programming language. In addition, the software codes may be stored in the memory 160 and executed by the controller 180.

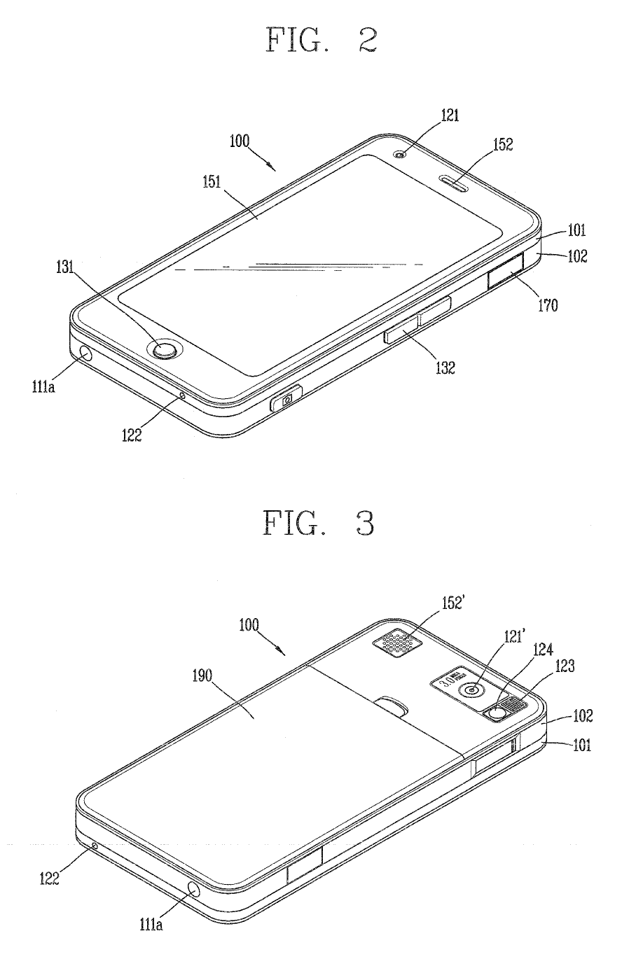

FIG. 2 is a front perspective view of the mobile terminal 100, and FIG. 3 is a rear perspective view of the mobile terminal shown in FIG. 2.

The mobile terminal 100 shown in FIG. 2 is a bar type mobile terminal. However, this detailed description may be applicable, but not limited to, a various structures, such as a slide type, a folder type, a swing type, a swivel type and the like, having two or more bodies coupled to be relatively movable with each other.

A body may include a case (or referred to as casing, housing, cover, etc.) defining an appearance of the mobile terminal 100. In this embodiment, the case may be divided into a front case 101 and a rear case 102. A space formed between the front and rear cases 101 and 102 may accommodate various electronic components. At least one intermediate case may further be disposed between the front and the rear cases 101 and 102. Such cases may be injected using a synthetic resin or be formed of a metal, such as stainless steel (STS), titanium (Ti) or the like.

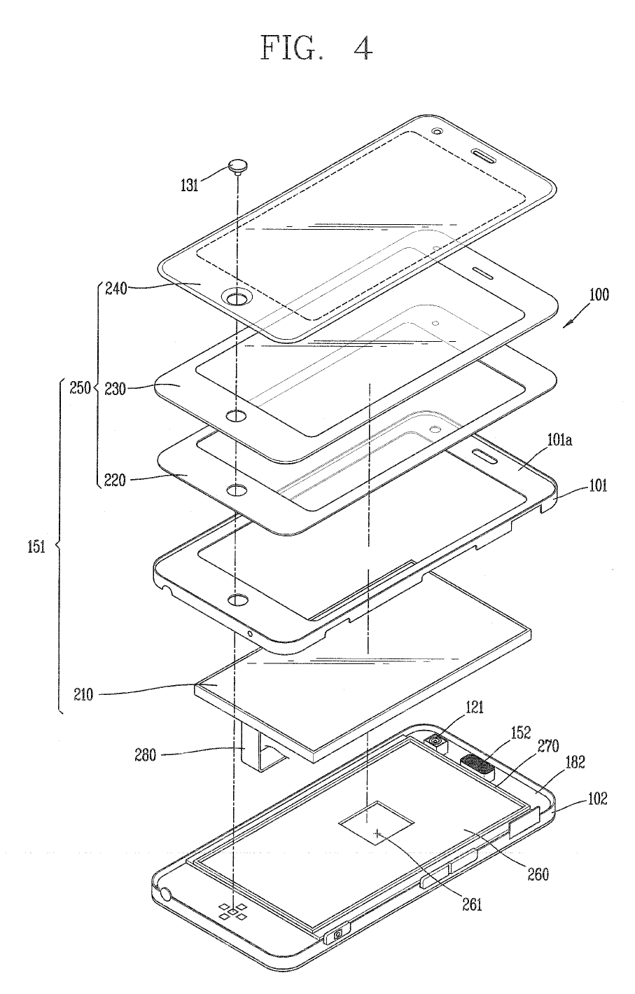

The terminal body has a display unit 151 having a display module 210 and a touch sensor assembly 250 (see FIG. 4). The terminal body also has an audio output module 152, a camera 121, a user input unit 130/131, 132, a microphone 122, an interface unit 170, and the like. The display module 200 may occupy most of a principal surface of the front case 101. The audio output module 152 and the camera 121 may be disposed near one of both end portions of the display module 210, and the user input unit 131 and the microphone 122 on the other end portion of the display module 210. The user input unit 132, the interface unit 170 and the like may be disposed on side surfaces of the front and rear cases 101 and 102.

The user input unit 130 may be manipulated to allow inputting of commands for controlling operations of the mobile terminal 100, and include a plurality of first manipulation units 131, 132. The plurality of manipulation units 131, 132 may be referred to as a manipulating portion. Such manipulating portion can employ any tactile manner that a user can touch or tap for manipulation.

The first and second manipulation units 131, 132 may be set to allow inputting of various contents. For example, the first manipulation unit 131 may be configured to input commands such as START, END, SCROLL or the like, and the second manipulation unit 132 may be configured to input commands, such as a volume adjustment of sound output from the audio output module 152, conversion of the display module 210 into a touch recognition mode, or the like. The touch sensor assembly 250 may configure a touch screen together with a touch sensor 220 (see FIG. 4), and the touch screen may be one example of the user input unit 130.

As shown in FIG. 3, a rear face of the terminal body, namely, the rear case 102 may further be provided with a camera 121′. The camera 121′ faces a direction which is opposite to a direction faced by the camera 121 (see FIG. 2), and may have different pixels from those of the camera 121.

For example, the camera 121 may operate with relatively lower pixels (lower resolution). Thus, the camera 121 may be useful when a user can capture his face and send it to another party during a video call or the like. On the other hand, the camera 121′ may operate with a relatively higher pixels (higher resolution) such that it can be useful for a user to obtain higher quality pictures for later use.

A flash 123 and a mirror 124 may additionally be disposed adjacent to the camera 121′. The flash 123 operates in conjunction with the camera 121′ when taking a picture using the camera 121′. The mirror 124 can cooperate with the camera 121′ to allow a user to photograph himself in a self-portrait mode.

An audio output module 152′ may further be disposed at a rear face of the terminal body. The audio output module 152′ can cooperate with the audio output module 152 (see FIG. 2) to provide stereo output. In addition, the audio output module 152′ may be configured to operate as a speakerphone.

A broadcast signal receiving antenna 116 may further be disposed at one side of the terminal body in addition to an antenna for communications, for example. The antenna 116 constituting a part of the broadcast receiving module 111 (see FIG. 1) may be retractable into the terminal body.

A power supply unit 190 for supplying power to the mobile terminal 100 may be mounted in the terminal body. The power supply unit 190 may be mounted in the terminal body or detachably coupled directly onto the outside of the terminal body.

The rear case 102 may be further provided with a touchpad for detecting a touch input. Similar to the display module 210, the touchpad may be implemented as a light-transmissive type. Here, if the display module 210 is configured to output visual information from both surfaces, the visual information can be recognized through the touchpad. The information output from the both surfaces may all be controlled by the touchpad. A display may further be mounted on the touchpad so as to configure a touch screen on the rear case 102.

The touchpad may operate cooperative with the display module 210 of the front case 101. The touchpad may be disposed at a rear side of the display module 210 in parallel to the display module 210. The touchpad may have a size the same as or smaller than that of the display module 210.

Hereinafter, description will be given in more detail of a mobile terminal 100 with a structure capable of protecting a display unit 151 when affected by external impact or exposed to high temperature.

FIG. 4 is a disassembled perspective view of the mobile terminal 100 of FIG. 2. As shown in FIG. 4, a printed circuit board 182 may be provided in an inner space defined by the front case 101 and the rear case 102. The printed circuit board 182 may function as one example of the controller 180 (see FIG. 1) for controlling various functions of the mobile terminal 100. As shown in FIG. 4, the audio output module 152 and the camera 121 may be mounted onto the printed circuit board 182.

A display module 210 may be disposed on one surface of the printed circuit board 182 to be electrically connected thereto. The display module 210 may display visual information and be obscured by a window 230. The display module 210 may have an area corresponding to a light-transmittable (transparent) area of the window 230.

A supporting member 260 for supporting the display module 210 may be provided between the display module 210 and the printed circuit board 182. The supporting member 260 may form a space in which the display module 210 is received. The supporting member 260 may be the front or rear case 101, 102, or an intermediate case between the front and rear cases 101 and 102.

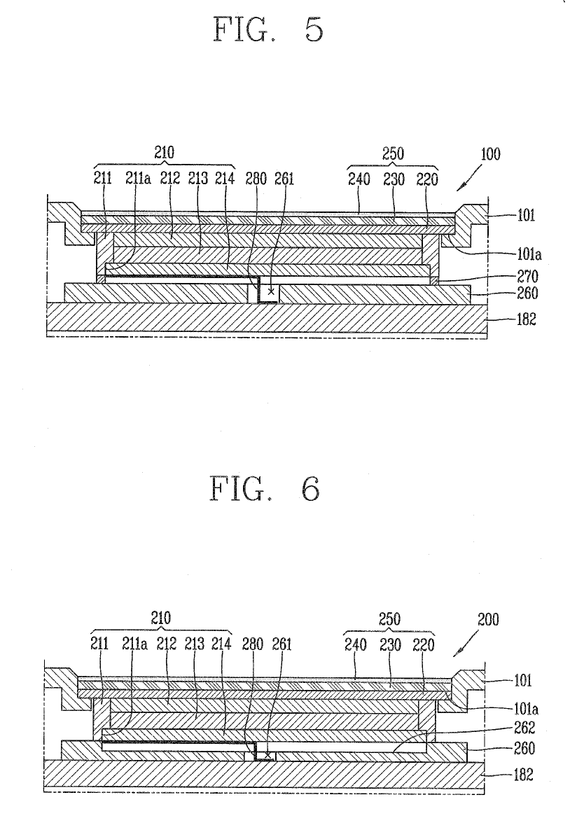

A contact restricting unit may be formed between the display module 210 and the supporting member 260 so as to space them from each other. FIG. 4 shows that the contact restricting unit is configured as a connection frame 270. The connection frame 270 may support a frame 211, which defines edges of the display module 210, with being interposed between the frame 211 and the supporting member 260 (see FIG. 5).

A receiving portion 101a may be recessed into one surface of the front case 101. The receiving portion 101a may have an area corresponding to a touch sensor assembly 250 such that the touch sensor assembly 250 can be received therein. The receiving portion 101a may include holes corresponding to the audio output module 152 and the camera 121, respectively.

The touch sensor assembly 250 may include a touch sensor 220 sensitive to a touch input, and a window 230 provided on the touch sensor 220. The touch sensor 220 may be present between the window 230 and the display module 210. The touch sensor 220 may convert the change in the quantity of electric charge generated at a specific portion into an electric input signal. The touch sensor 220 may be transparent to allow for transmission of an image formed at the display module 210. An area of the touch sensor 220, which corresponds to a transparent region of the window 230, may define an input area.

The window 230 may be coupled to one surface of the touch sensor 220. The window 230 may be made of a light-transmittable (transparent) material, for example, light-transmittable synthetic resin, tempered glass and the like. The window 230 may include an opaque region where light cannot be transmitted. The transparent region of the window 230 may be as wide as the display module 210. Accordingly, a user can recognize visual information output on the display module 210.

A touch film 240 for protecting the window 230 from an external environment may be provided on the window 230. The touch film 240 may be formed of a transparent material, such as Polycarbonate (PC) and Polyethylene Terephthalate (PET). The touch film 240 may include an opaque region. As shown in FIG. 4, the touch film 240 may be configured such that a central region corresponding to the display module 210 can be transparent and the edge region can be opaque.

A sound (audio) hole corresponding to the audio output module 152 and an image window corresponding to the camera 121 may be formed at one end portion of each of the touch sensor 220, the window 230 and the touch film 240. The image window may be separately made of a transparent material, or be integrally formed with the touch sensor 220, the window 230 and the touch film 240.

Referring to FIG. 5 together with FIG. 4, the display module 210, which is electrically connected to the printed circuit board 182, may be mounted onto one surface of the supporting member 260. The display module 210 may include a frame 211, a liquid crystal (LC) panel 212, a backlight unit 213 and a reflection sheet 214.

The frame 211 may create a hollow portion for accommodating an LC panel 212 and a backlight unit 213, and form a frame such that those components can be mounted in the mobile terminal 100.

The LC panel 212 may be received in the hollow portion, and provided with a display region where an image is displayed. The LC panel 212 may control an image by selectively transmitting light using an effect that a direction of LC molecules changes when voltage is applied to the LC panel.

The backlight unit 213 may be provided at the rear of the LC panel 212, so as to emit light toward the LC panel 212. The backlight unit 213 may include lamps, a light guide plate (LGP), a diffusion sheet and a prism sheet. The lamps may emit light toward the LC panel 212. The lamps may be disposed at a rear surface or a side surface of the LGP. The lamps, for example, may be a plurality of light emitting diodes (LEDs) emitting light. The LGP may guide light emitted from the lamps such that the light can be uniformly distributed over the entire display region.

The diffusion sheet may be provided on the LGP and diffuse light transmitted through the LGP. A preset pattern for an efficient diffusion of light may be consecutively formed on the surface of the diffusion sheet. The diffusion of light by the diffusion sheet may result in uniformity of light but causes degradation of brightness of the light. The prism sheet may include prism patterns so as to increase luminance of light by refracting and condensing the light from the diffusion sheet.

A passivation sheet for protecting the prism sheet and diffusing light having a viewing angle narrowed due to the prism sheet may be disposed on the prism sheet.

The reflection sheet 214 may be provided at a rear surface of the backlight unit 213, especially the LGP, to reflect light leaked to the lower side of the LGP back to the LGP, thereby preventing light leakage. A surface of the reflection sheet 214, namely, a surface facing the LGP, may be a specular surface to have high reflectivity, similar to glass.

The reflection sheet 214 may be fixed to the frame 211 to obscure the hollow portion, thereby forming a bottom surface of the display module 210. In detail, a recess 211a may be recessed into the inner surface of the frame 211 to receive an edge portion of the reflection sheet 214, and the reflection sheet 214 may be coupled to the frame 211 by virtue of the insertion into the recess 211a. Hence, the reflection sheet 214 is able not only to support the LC panel 212 and the backlight unit 213 but also to form the bottom surface of the display module 210, thereby creating a slimmer mobile terminal 100.

The display module 210 may be electrically connected to the printed circuit board 182, which is provided at the rear surface of the supporting member 260, via a flexible printed circuit board 280. In detail, one end of the flexible printed circuit board 280 may be connected to the display module 210 and the other end may be connected to the printed circuit board 182 through a through hole 261 formed through the supporting member 260.

With the configuration, the flexible printed circuit board 280 may be present between the reflection sheet 214 and the supporting member 260 to form a stair-step. Accordingly, the LC panel 212 may be damaged when an external impact is applied. In addition, even if the supporting member 260 is formed to be even, a perfect evenness cannot be expected. Furthermore, when being exposed to high temperature, the reflection sheet 214 may be deformed and thereby contact the supporting member 260, which causes damage to the LC panel 212.

In order to prevent such damage from being caused by contact between the frame 211 and the supporting member 260, the contact restricting unit may be provided to space the reflection sheet 214 from the supporting member 260. The contact restricting unit may be the connection frame 270 which makes the display module 210 spaced apart from the supporting member 260 by a preset interval. As shown in FIG. 4, the connection frame 270 may have a loop shape corresponding to the edges of the display module 210, namely, the frame 211.

The connection frame 270 may extend from the frame 211, thereby forming a space between the reflection sheet 214 and the supporting member 260. In addition, the connection frame 270 may be firmly coupled to the supporting member 260 by bonding or coupling units. For example, stopping hooks may protrude from the connection frame 270 toward the supporting member 260 with preset intervals. Stopping recess may be formed at portions of the supporting member 260, which correspond to the stopping hooks, such that the stopping hooks can be fixedly inserted in the stopping recess, respectively.

With the connection frame 270 being used to space the reflection sheet 214 apart from the supporting member 260, the display module 210 can be protected when being subjected to an external impact by acting as a shock absorber or exposed to high temperature. To achieve this function, the connection frame 270 may be made of any suitable material, such as a resilient material. The connection frame 270 may be made of an elastically transformable material, for example, Polyethylene Terephthalate (PET).

FIG. 6 is a sectional view showing another embodiment of a mobile terminal 200. In this embodiment, a contact restricting unit may be configured as a recess portion 262 in a top surface of the supporting member 260 that faces the reflection sheet 214 such that the reflection sheet and the supporting member 260 can be spaced apart from each other. The recess portion 262 may have an area corresponding to the reflection sheet 214 and be recessed by a specific depth.

The frame 211 may be fixed to the top surface of the supporting member 260, and the reflection sheet 214 may be spaced apart from the surface of the recess portion 262 by a preset interval. Accordingly, even when being affected by an external impact or exposed to high temperature, the reflection sheet 214 may not contact the supporting member 260. Consequently, it may be possible to provide the display module 210 having improved reliability, in the aspect of protection of the display module 210 even in various external environments, and the mobile terminal 200 having the display module 210.

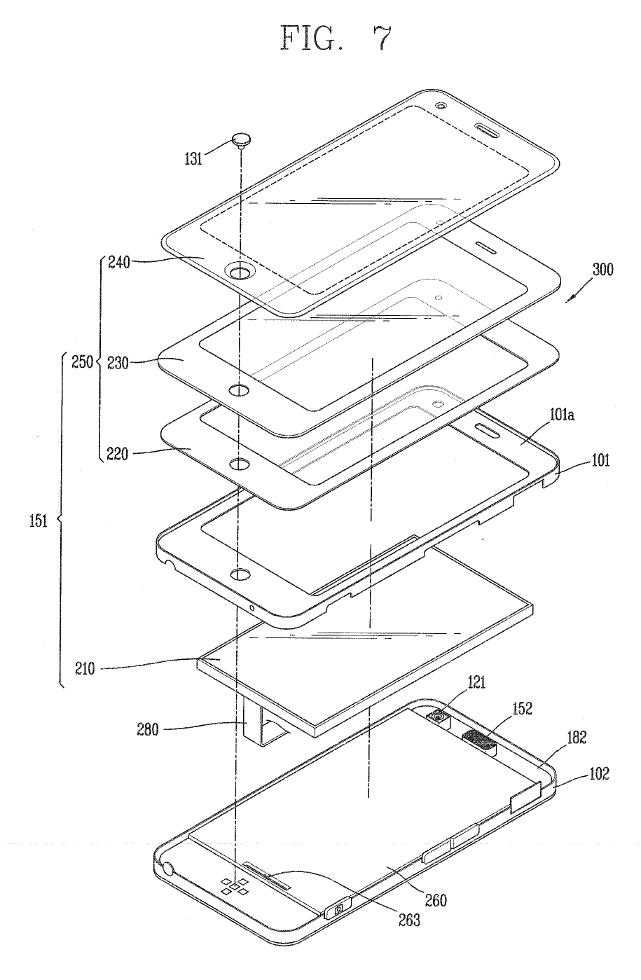

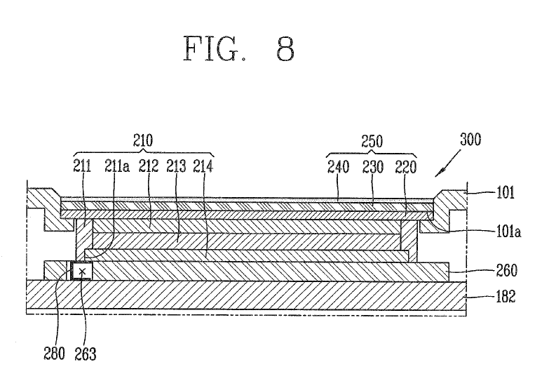

FIG. 7 is a disassembled perspective view showing another embodiment of a mobile terminal 300, and FIG. 8 is a sectional view of the mobile terminal 300 shown in FIG. 7. As shown in FIGS. 7 and 8, a contact restricting unit may include a through hole 263 formed through one surface of the supporting member 260 such that the flexible printed circuit board 280 can be inserted therethrough. The flexible printed circuit board 280 may be inserted through the through hole 263. The flexible printed circuit board 280 may be disposed outside a space between the reflection sheet 214 and the supporting member 260, which creates a structure without a stair-step.

With the configuration, the flexible printed circuit board 280 may not contact the display module 210 upon being subjected to an external impact or exposed to high temperature, thereby reducing damage of the display module 210.

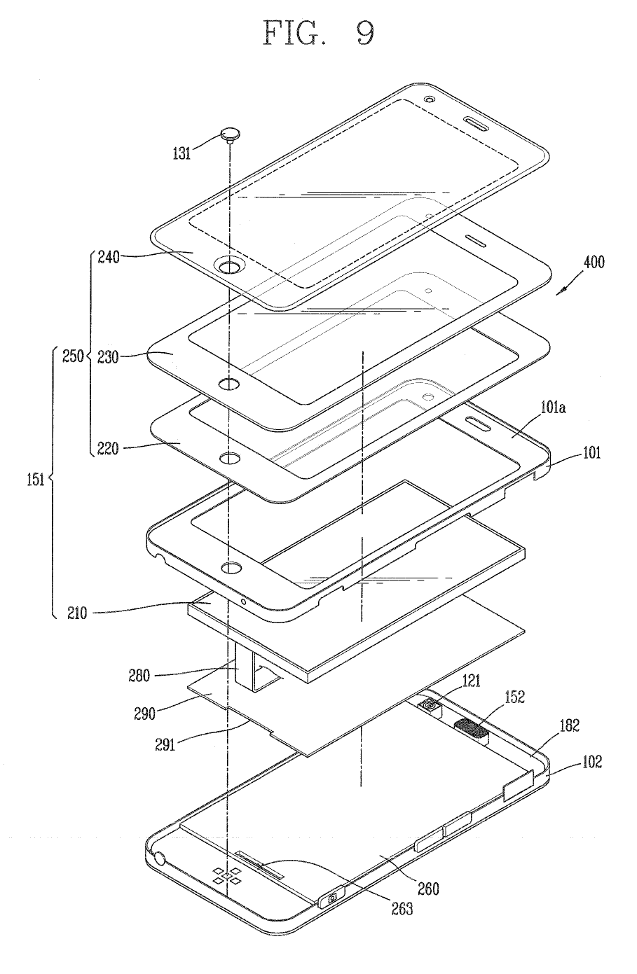

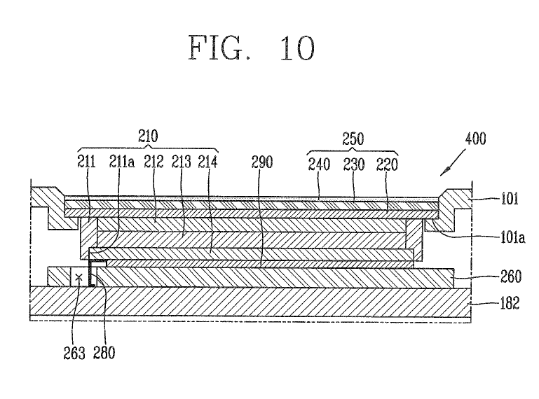

FIG. 9 is a disassembled perspective view showing another embodiment of a mobile terminal 400, and FIG. 10 is a sectional view of the mobile terminal 400 shown in FIG. 9. As shown in FIGS. 9 and 10, a contact restricting unit may include a damping sheet 290 interposed between the reflection sheet 214 and the supporting member 260. The damping sheet 290 may adsorb impact transferred to the reflection sheet 214. To achieve this function, the damping sheet may be made of any suitable material, such as a resilient material.

The damping sheet 290 may be made of an elastically transformable material, for example, Polyethylene Terephthalate (PET). An area of the damping sheet 290 may be as wide as the reflection sheet 214, and attached onto a rear surface of the reflection sheet 214 to be a part of the display module 210.

The damping sheet 290 may include a recess 291 or a hole defining a space through which the flexible printed circuit board 280 can be inserted. While the recess is shown at an edge of the damping sheet 290, it may be formed as a hole spaced inwardly from the edge. The flexible printed circuit board 280 may be connected to the printed circuit board 182 through the recess 291 or hole, and disposed with overlapping a reflection sheet 214, the damping sheet 290 or the supporting member 260.

With the configuration, the contact restricting unit may be formed to space the reflection sheet 214 apart from the supporting member 260, so as to protect the display module 210 when being subjected to an external impact or exposed to high temperature.

In addition, the reflection sheet 214 may be fixedly disposed to obscure the hollow portion of the frame 211, and accordingly the reflection sheet 214 itself can create the bottom surface of the display module 210, thereby implementing the slimmer mobile terminal 100, 200, 300, 400.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the embodiments described herein may be combined in various ways to obtain additional and/or alternative embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A mobile terminal comprising:
a frame having a hollow portion;
a liquid crystal panel received in the hollow portion, the liquid crystal panel forming an image thereon;
a backlight unit disposed at the rear of the liquid crystal panel to emit light toward the liquid crystal panel;
a reflection sheet disposed at the rear of the backlight unit and fixed to the frame to obscure the hollow portion, the reflection sheet reflecting light leaked to a lower side of the backlight unit;
a supporting member forming a space to place the frame thereon, the supporting member supporting the frame; and
a contact restricting unit to space the reflection sheet apart from the supporting member.

2. The terminal of claim 1, wherein the contact restricting unit is disposed between the frame and the supporting member, the contact restricting unit comprising a connection frame protruding from the reflection sheet.

3. The terminal of claim 2, wherein the connection frame extends from the frame.

4. The terminal of claim 1, wherein the contact restricting unit comprises:
a recess portion formed in a top surface of the supporting member, the top surface of the supporting member facing the reflection sheet.

5. The terminal of claim 4, wherein the frame is fixed onto the top surface of the supporting member, and the reflection sheet is spaced apart from a surface of the recess portion by a preset interval.

6. The terminal of claim 1, further comprising:
a flexible printed circuit board electrically connected to the liquid crystal panel,
wherein the contact restricting unit comprises a through hole formed through one surface of the supporting member such that the flexible printed circuit board can be inserted therethrough.

7. The terminal of claim 1, wherein the contact restricting unit comprises a damping sheet disposed between the reflection sheet and the supporting member to adsorb impact transferred to the reflection sheet.

8. The terminal of claim 7, wherein the damping sheet is attached to a rear surface of the reflection sheet.

9. The terminal of claim 1, wherein the frame has a recess on an inner surface to receive an end portion of the reflection sheet, and
wherein the reflection sheet is inserted into the recess to be fixed to the frame so as to support the liquid crystal panel and the backlight unit.

10. A mobile terminal comprising:
a display module having a frame, the frame creating a hollow portion, and the display module configured to display visual information;
a reflection sheet fixed to the frame to form a bottom surface, the reflection sheet reflecting light leaked to a lower side of a backlight unit;
a housing having a receiving portion forming a space for reception of the display module therein, the housing supporting the frame; and
a contact restricting unit to space the display module apart from the receiving portion of the housing.

11. The terminal of claim 10, wherein the contact restricting unit has a connection frame extending from the frame and protruding from the reflection sheet.

12. The terminal of claim 10, wherein the contact restricting unit has a recess portion formed in a bottom surface of the housing, the bottom surface of the housing facing the reflection sheet.

13. The terminal of claim 10, wherein the contact restricting unit comprises:
a damping sheet disposed between the reflection sheet and the housing to adsorb impact transferred to the reflection sheet.

14. The terminal of claim 13, wherein the contact restricting unit comprises:
a through hole formed through one surface of the housing to allow a flexible printed circuit board to be inserted therethrough, the flexible printed circuit board electrically connected to the display module,
wherein the flexible printed circuit board obscures a rear surface of the housing.

15. A mobile terminal comprising:
a frame having a hollow portion;
a display module received in the hollow portion, the display module having a top surface and a bottom surface;
a supporting member forming a space to place the frame thereon, the supporting member supporting the frame; and
a contact restricting unit spacing the display module from the supporting member, the contact restricting unit made of resilient material.

16. The mobile terminal of claim 15, wherein the display module comprises:
a liquid crystal panel, the liquid crystal panel forming an image thereon;
a backlight unit disposed at the rear of the liquid crystal panel to emit light toward the liquid crystal panel; and
a reflection sheet disposed at the rear of the backlight unit and fixed to the frame to obscure the hollow portion, the reflection sheet forming the bottom surface of the display module.

17. The mobile terminal of claim 15, wherein the contact restricting unit is a solid sheet of material.

18. The mobile terminal of claim 15, wherein the contact restricting unit has a central aperture substantially equal to the size of the display module bottom surface.

19. The mobile terminal of claim 15, wherein the contact restricting unit is integrally formed with the supporting member.

20. The mobile terminal of claim 15, further comprising:
a printed circuit board under the supporting frame;
an aperture in the supporting frame; and
a flexible printed circuit board connected to the display module and the printed circuit board, the flexible printed circuit board passing through the aperture.
